(19) United States
(12) Patent Application Publication
(10) Pub. No.: US 2006/0024440 A1
(43) Pub. Date: Feb. 2, 2006

(54) Reduced oxygen arc spray

(75) Inventors: Kenneth Tsai, Emerald Hills, CA (US); Kenny King-Tai Ngan, Fremont, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/901,319

(22) Filed: Jul. 27, 2004

(51) Int. Cl. C23C 16/00; B05D 1/32

(52) U.S. Cl. 427/248.1; 427/282

(57) ABSTRACT

A method of forming a coating on a component surface comprises placing a shield about the component surface to define a process zone, controlling the level of oxygen present in the process zone, generating an electric arc in the process zone to form a liquefied material from an electrode, and injecting a carrier gas into the process zone to direct the liquefied material toward the component surface. The level of oxygen present in the process zone is controlled by (i) filling the process zone with a non-oxidizing gas and maintaining a pressure p₁ in the process zone higher than a pressure p₂ of an ambient environment external to the process zone, and (ii) lining the process zone with an oxygen-absorbing material. Additionally, an arc spray apparatus comprises the shield comprising the oxygen-absorbing material and a consumable electrode extending into the process zone.

### BACKGROUND

The present invention relates to arc spraying of coatings on a substrate processing component.

Substrate processing components used in many applications are coated with select materials to improve their performance. For example, in the processing of a substrate in a process chamber, as in the manufacture of integrated circuits and displays, the substrate is typically exposed to energized gases that are capable of etching or depositing material on the substrate. The energized gases, however, often comprise corrosive gases that can erode components of the chamber. The corroded portions of the components can flake off and contaminate the substrate, which reduces the substrate yield. The corrosion resistance of a chamber component can be improved by forming a coating of a corrosion resistant material over surfaces of the component that are exposed to the energized gas.

An arc spray process can be used to produce a coating on a surface of a substrate processing component. In an arc spray process, a voltage is applied between two electrodes such as, for example, metal wires, to create an arc between the electrodes which produces liquefied material from one or both electrodes. The liquefied material is directed toward the component to form the coating typically by using a pressurized gas. Existing arc spray processes, however, have certain disadvantages. It may be difficult to control the chemical composition of the coating produced by the arc spray process. For example, oxygen in the environment in which the arc spray process is conducted may oxidize or partially oxidize the liquefied material, and thus, the resulting coating may contain oxides of the electrode material in addition to the electrode material itself. As properties of a coating are often closely tied to its chemical composition, an undesirable or uncontrolled inclusion of oxygen along with the electrode material in the coating can undesirably influence the properties and usefulness of the coating.

Some methods have been used to limit or reduce the oxidation of the liquefied electrode material during the arc spray process. For example, U.S. Patent Application Publication No. 2002/0038690 to Minato et al., filed Oct. 1, 2001, which is herein incorporated by reference in its entirety, discloses enclosing an arc spray gun in an inert gas atmosphere created in a spraying container. The spraying container is evacuated with a vacuum pump and the inert gas is supplied to the spraying container. Spraying material, blowing gas, and power are also supplied to the arc gun within the spraying container. The arc gun is operated by a human operator using a rubber glove mounted in a wall of the spray container. However, this approach has several limitations. The arc spray system described by Minato et al. is relatively equipment and maintenance intensive, requiring vacuum pumps, vacuum seals and dedicated space in a fabrication facility to locate the spray container. The enclosed process environment created by the spray container is also of a fixed shape and size, which may create difficulties in coating large or unusually shaped components. The mounted rubber glove interface also may limit the range of movement and operating flexibility of the operator, resulting in a non-uniform or uneven coating on a component having a convoluted or complex surface topography.

Thus, there is a need for a process to produce high quality coatings on components. There is also a need for an arc spray process to produce coatings with controlled or reduced oxygen content. There is further a need for an arc spray process which is not excessively dependent on the size or volume of equipment.

### SUMMARY

A method of forming a coating on a component surface comprises placing a shield about the component surface to define a process zone, controlling the level of oxygen present in the process zone, generating an electric arc in the process zone by applying a voltage between first and second electrodes to form a liquefied material from at least one of the electrodes, and injecting a carrier gas into the process zone to direct the liquefied material toward the component surface to form the coating on the component surface. The level of oxygen present in the process zone is controlled by (i) filling the process zone with a non-oxidizing gas and maintaining a pressure p₁ in the process zone higher than a pressure p₂ in an ambient environment external to the process zone, and (ii) lining the process zone with an oxygen-absorbing material.

In one version, a separation gap is maintained between the shield and the component surface and the non-oxidizing gas is injected into the process zone at a flow rate sufficiently high to prevent gases in the ambient environment from entering the process zone through the separation gap and sufficiently low as to not disrupt the directing of the liquefied material toward the component surface. In one version, the separation gap comprises a gap distance of about 0.1 cm to about 1.0 cm. Additionally, in one version, the shield comprises the oxygen-absorbing material. The oxygen-absorbing material may comprises an iron-containing material, silicon, a carbon-containing material, a transition-metal-containing material, ferrous oxide, ascorbic acid, isoascorbic acid, a sulfite, an alkali metal carbonate, or mixtures thereof.

In another aspect, an arc spray apparatus comprises a shield to define a process zone and a consumable electrode extending into the process zone. The shield comprises an oxygen-absorbing material. In one version, the shield comprises a body having a coating and the coating comprises the oxygen-absorbing material. The oxygen-absorbing material may comprise an iron-containing material, silicon, a carbon-containing material, a transition-metal-containing material, ferrous oxide, ascorbic acid, isoascorbic acid, a sulfite, an alkali metal carbonate, or mixtures thereof.

In one version, the shield has a surface comprising the oxygen-absorbing material and the surface has surface features that increase its surface area. The surface comprising the oxygen-absorbing material may also have a roughness of from about 100 micro-inches to about 1,000 micro-inches. The surface comprising the oxygen-absorbing material can be porous. The arc spray apparatus may also comprise a guide to feed the consumable electrode into the process zone and apply a voltage to the consumable electrode and a gas outlet to deliver a pressurized gas to the process zone. The arc spray apparatus can also have a second gas outlet to deliver a second pressurized gas to the process zone.

### DRAWINGS

These and other features, aspects, and advantages of the present invention will become better understood with regard to the following description, appended claims, and accompanying drawings, which illustrate examples of the invention, where:

FIG. 1 is a flow chart of an embodiment of a process to form a coating on a component;

FIG. 2 is a schematic view of an embodiment of an arc spray apparatus; and

FIGS. 3a-d are sectional views of an embodiment of a shield comprising an oxygen-absorbing material.

### DESCRIPTION

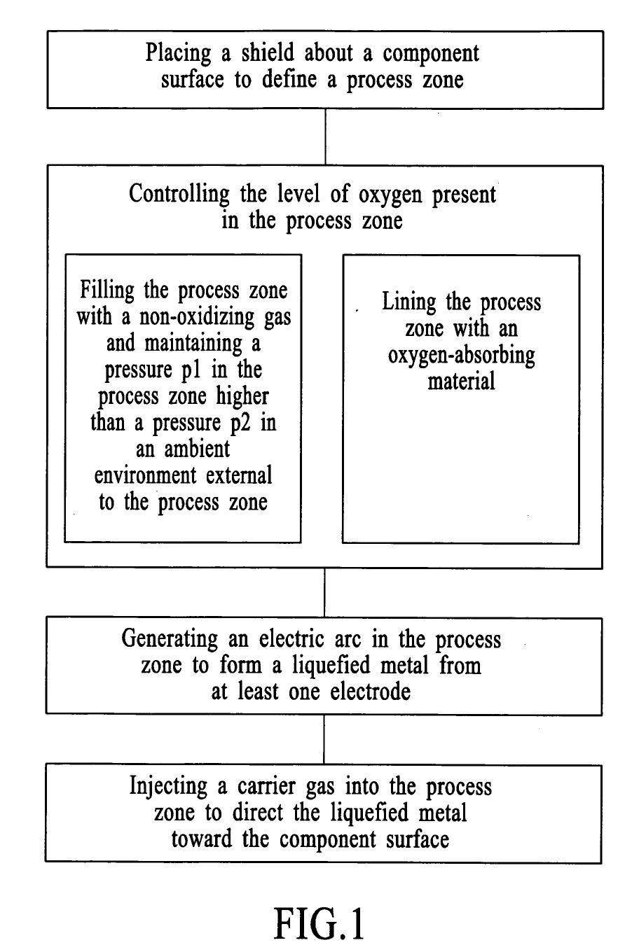

A coating formed according to the present process exhibits reduced oxygen content, or even a controlled predetermined oxygen content. Controlling the oxygen content in the coating can provide better corrosion resistance or desirable values of electrical conductivity or dielectric constant. One version of the method of forming a reduced-oxygen coating on a component surface is shown in the flow chart of FIG. 1. In the method, a component surface is shielded to define a process zone about a portion of the component surface upon which the coating is to be formed. Shielding the component surface isolates the process zone from the ambient environment to prevent ambient gases such as, for example, gases containing oxygen, from entering the process zone. The process zone has a size suitable to conduct the process and may comprise, for example, dimensions on the order of a few centimeters.

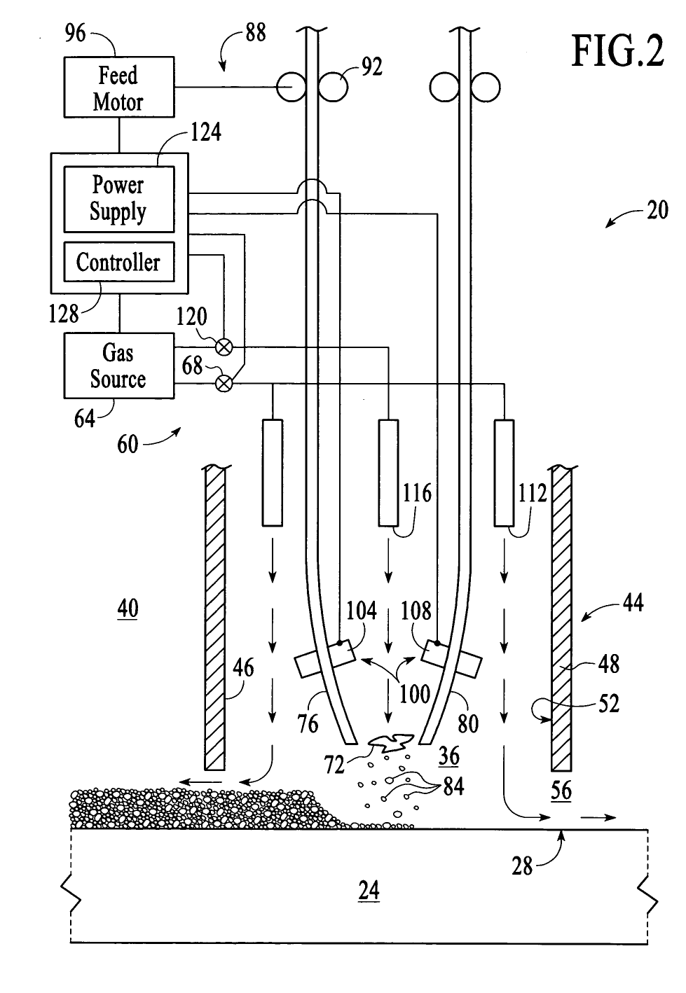

A reduced-oxygen coating 32 can be formed by an arc spray apparatus 20 as schematically illustrated in FIG. 2. Generally, the arc spray apparatus 20 comprises a shield 44 having a body 48 with a geometry which defines the process zone 36 around the portion of the component surface 28 upon which the coating 32 will be formed. As shown, the shield 44 also encloses portions of components of the arc spray apparatus 20 that enter the process zone 36. For example, in the version shown, the shield 44 comprises a roughly cylindrical shape; however, the shield 44 can comprise a number of other shapes or geometries, including square, rectangular, circular, arcuate, or combination shapes.

In the arc spraying method, the level of oxygen present in the process zone 36 about the component surface to be coated, is reduced or controlled to the obtain a desired oxygen content in the coating 32. Oxygen may become included in the coating 32, for example, by the oxidation of materials in the process zone 36 during the coating process. Thus, in one version, the level of oxygen present in the process zone 36 is reduced by lining the process zone 36 with an oxygen-absorbing material 46 which absorbs oxygen present in the process zone 36. Oxygen may be present in the process zone 36, for example, as remnants of the quiescent state of the process zone 36 before the process is initiated as well as due to other causes such as, for example, faulty or non-hermetic seals at interfaces of the arc spray apparatus 20. The oxygen-absorbing material 46 reduces the oxygen in the process zone 36 to a suitable or controlled level. The level of oxygen present in the process zone 36 is selected to control the amount of oxygen included in the coating 32. For example, it may be desirable to produce a metallic coating 32 having a reduced level of oxygen. In one version, it may be desirable to produce an aluminum coating 32 having an oxygen content of from about 0.01% to about 0.1% by weight. In this version, the level of oxygen present in the process zone 36 is reduced to about 100 ppm to about 1,000 ppm. This type of reduced oxygen aluminum coating 32 is advantageous, for example, for coating process kit components or for refurbishing aluminum targets for substrate processing chambers such as physical vapor deposition chambers. This type coating 32 is advantageous because a reduced oxygen content aluminum coating 32 has improved properties such as more desirable values of the density, strength or structural integrity of the coating 32.

The oxygen-absorbing material 46 may comprise a material having a suitable capability to absorb oxygen. The oxygen absorbing capability of the oxygen-absorbing material 46 is selected according to the type of coating 32 that is desirable to form. In one version, for example, it may be desirable to select an oxygen-absorbing material 46 with a high degree of oxygen absorption. In another version, the desired level of oxygen absorption may be less. The oxygen absorbing material 46 may comprise a number of materials such as, for example, an iron-containing material, silicon, a carbon-containing material, a transition-metal-containing material, ferrous oxide, ascorbic acid, isoascorbic acid, a sulfite, an alkali metal carbonate or mixtures thereof. Advantages to using an iron-containing material, for example, include the ability of a relatively small amount of an iron-containing material to absorb a relatively large amount of oxygen. For example, in one version, about 1 g of iron is capable of reacting with about 30 milliliters of oxygen. Additionally, other materials not listed above can be used as the oxygen-absorbing material 46. For example, the oxygen-absorbing material 46 may comprise any material that absorbs, attracts, condenses or otherwise removes oxygen from the process zone 36.

In one version, the process zone 36 is lined with the oxygen-absorbing material 46 by having a shield 44 which comprises the oxygen-absorbing material 46. For example, the shield body 48 may comprise the oxygen absorbing material 46. In another version, the body 48 of the shield 44 has a coating 50 which comprises the oxygen absorbing material 46. For example, the body 48 of the shield 44 can have a coating 50 comprising the oxygen-absorbing material 46 on substantially all the surfaces of the body 48 that are exposed to the process zone 36. In another embodiment, the shield 44 may have both a body 48 comprising a first oxygen absorbing material 46 and a coating 50 comprising a second oxygen absorbing material 46. The coating 50 comprising the oxygen absorbing material 46 has a thickness selected to provide a suitable level of oxygen absorption. For example, in one version, the coating 50 on the shield body 48 has a thickness of from about 25 μm to about 1,000 μm. However, the thickness of the coating 50 may vary and may depend upon the type of oxygen absorbing material 46 that is used. In another version, other components of the arc spray apparatus 20 that are exposed to the process zone 36, in addition to the shield 48, may comprise the oxygen-absorbing material 46.

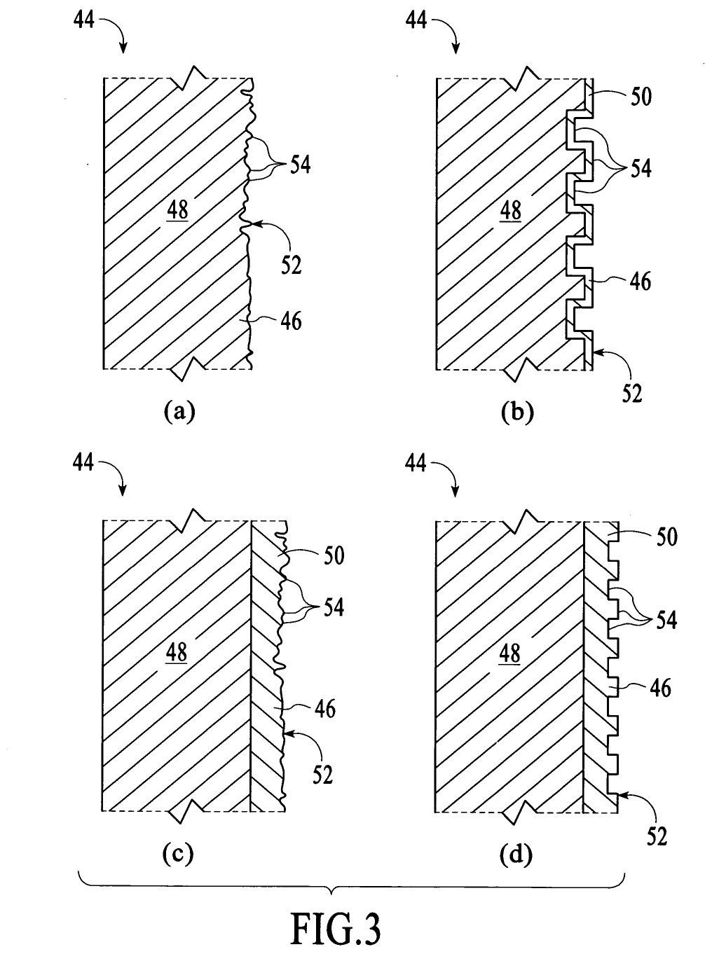

In one version, the shield 44 has a surface 52 comprising the oxygen-absorbing material 46. The surface 52 may be a surface of the shield body 48, a surface of the coating 50, or a combination of surfaces of the shied body 48 and the coating 50. The surface 52 comprising the oxygen absorbing material 46 may comprise surface features 54 that increase its ability to absorb oxygen, as illustrated in FIGS. 3a-d. The surface features 54 may increase the oxygen absorption by, for example, increasing the surface area of the oxygen absorbing material 46 that is exposed to the process zone 36. The surface features 54 may comprise physical features and characteristics of the surface 52. For example, the surface features 54 may comprise pores, bumps, depressions, grooves, edges, and other types of physical features. The surface 52 having the surface features 54 may also comprise a roughened surface. In one version, the surface 52 comprising the oxygen-absorbing material 46 has a roughness of from about 100 micro-inches to about 1,000 micro-inches. For example, the surface 52 having the surface features 54 may comprise a surface 52 having an amorphous surface profile produced by a roughening process such as bead blasting or chemical etching. The surface features 54 may also comprise an ordered pattern of features 54. For example, the surface features 54 may comprise an array of repeated features 54 such as bumps or depressions.

The shield body 48 or the shield coating 50 can be processed to produce the surface features 54. For example, as shown in FIG. 3a, the shield body 48 comprising the oxygen-absorbing material 46 can processed to create the surface 52 having the surface features 54. In another version, as shown in FIG. 3b, the shield body 48 comprising a non-oxygen-absorbing material can be processed, and a coating 50 comprising the oxygen absorbing material 46 can then be formed on the shield body 48 to create the surface 52 comprising the oxygen-absorbing material 46 having the surface features 54. In other versions, as shown in FIGS. 3c and 3d, the coating can be processed to create the surface features. For example, a shield body 48 not having the surface features 54 can receive the coating 50 comprising the oxygen absorbing material 46, and the surface 52 of the coating 50 can then be processed to create the surface features 54. The shield body 48 or the shield coating 50 can be processed to create the surface features 54 by roughening, etching, patterning, milling, laser-drilling, or otherwise manipulating the body 48 or the coating 50 to create the surface features 54.

The level of oxygen present in the process zone 36 can also be reduced or controlled by filling the process zone with a non-oxidizing gas and maintaining a pressure difference between the process zone 36 and an ambient environment 40 external to the process zone 36. For example, a pressure p₁ in the process zone 36 can be created and maintained in the process zone 36 that has a greater value than a pressure p₂ in the ambient environment 40. The pressure differential between the process zone 36 and the ambient environment 40 prevents gases present in the ambient environment 40 from entering the process zone 36. For example, the pressure differential prevents oxygen-containing gases which may be present in the ambient environment 40 from entering the process zone 36. In one version, the pressure differential is set up to provide a pressure p₁ and a pressure p₂ such that the ratio of the two pressures, p₁:p₂, is from about 1.5:1 to about 4:1.

The pressure differential between the process zone 36 and the ambient environment 40 can be created and maintained by injecting the non-oxidizing gas into the process zone 36. The non-oxidizing gas may comprise, for example, argon, helium, neon, nitrogen or mixtures thereof. The non-oxidizing gas gradually leaks out of the shielded process zone 36 into the ambient environment 40. The flow of the non-oxidizing gas from the process zone 36 to the ambient environment 40 is restricted to create a localized higher pressure region within the process zone 36 with respect to the ambient environment 40. For example, the flow of the non-oxidizing gas from the process zone 36 to the ambient environment 40 can be restricted by forming a selectively sized channel or pathway through the shield 44 to the ambient environment 40. The size or shape of the channel can be selected to control the degree to which the non-oxidizing gas is allowed to leak into the ambient environment 40, thus controlling the extent of the pressure differential. The non-oxidizing gas is injected into the process zone 36 at a flow rate sufficiently high to prevent ambient gases from entering the process zone 36 through the channel in the shield and sufficiently low as to not disrupt the directing of liquefied material toward the component surface 28.

In one version, as shown in FIG. 2, the arc spray apparatus 20 comprises a separation gap 56 between the shield 44 and the component surface 28 at the perimeter of the portion of the component surface 28 in the process zone 36 defined by the shield 44. The separation gap 56 forms the channel through the shield and comprises a gap distance having a value that is selected to provide for the generation of a pressure differential between the process zone 36 and the ambient environment 40. For example, the gap distance is selected to be sufficiently small to force the injected pressurized gas to leak out of the process zone 36 suitably slowly such that a localized higher pressure region is created in the process zone 36 which prevents ambient gases from entering the process zone 36. Various gap distances are possible, depending upon the configuration of the shield 44 and the pressure and flow rate of the injected non-oxidizing gas. For example, in one version, the gap distance is selected to be from about 0.1 cm to about 1.0 cm and the non-oxidizing gas is held at a pressure of from about 1 atm to about 10 atm and injected into the process zone 36. The non-oxidizing gas can be injected into the process zone 36 by a gas supply 60 that comprises a gas source 64 such as a container capable of holding a pressurized gas. The gas supply 60 may also comprise a gas valve 68 to control the flow of the non-oxidizing gas, and in some versions may further comprise a conduit, or a combination of additional valves and conduits to facilitate and control the flow the non-oxidizing gas.

The method to form the coating 32 also comprises generating an electric arc 72 in the process zone 36. The electric arc 72 is generated by applying a voltage between a first 76 and a second electrode 80. In one version, at least one of the first and second electrodes 76, 80 is consumable and the electric arc 72 at least partially liquefies the consumable electrode in the process zone 36 to generate liquefied particles 84 of the electrode material. The voltage applied to the electrodes 76, 80 is sufficiently great to generate an arc 72 having enough energy to liquefy the electrode. The liquefied electrode material 84 is generated in a region about the electrodes 76, 80 and comprises the material of the coating 32 formed by the process. Reducing the level of oxygen in the process zone 36, as discussed above, is important to prevent the oxidation of the liquefied particles 84 of electrode material.

In one version, the arc spray apparatus 20 comprises first and second electrodes 76, 80 that are independent from and positioned above the component surface 28. For example, in the version shown in FIG. 2, the arc spray apparatus 20 comprises two electrodes 76, 80 which are metal wires. The metal wire can comprise a cylindrical shape or other shape, such as a strip of metal. The wire comprises a material of which it is desired to form the coating 32. The arc spray apparatus 20 can comprise first and second electrodes 76, 80 that are both consumable electrodes. In another version, the arc spray apparatus 20 may comprise one consumable electrode and one non-consumable electrode. Additionally, a separate consumable metal wire that does not serve as an electrode can be inserted into the electric arc 72 in the process zone 36 to provide a source of the liquefiable material. In yet another version, the component surface 28 may be one of the electrodes.

The consumable electrode can be continuously fed into the process zone 36 to provide a continuous source of consumable material. In one version, the arc spray apparatus 20 comprises an electrode feed 88 to feed the consumable electrode into the process zone 36. The electrode feed 88 may comprise, for example, as shown in FIG. 2, a roller 92 to grip and feed the electrode material and an feed motor 96 to turn the roller 92. However, other versions of electrode feed 88 may comprise alternative components.

In one version, the arc spray apparatus 20 comprises a guide 100 to position the electrodes 76, 80 above the component surface 28. The guide 100 positions the first and second electrodes 76, 80 towards each other to allow for formation of the electric arc 72 near the closest point between the electrodes 76, 80. Typically, the first and second electrodes 76, 80 are positioned at an angle to each other. The guide 100 may also apply the voltage to the electrodes 76, 80 to generate the electric arc 72. For this purpose, the guide 100 can be divided into several electrically independent portions. For example, the guide can be divided into first and second electrically independent portions 104, 108 that supply different voltages to the first and second electrodes 76, 80. The guide 100 can comprise a relatively conductive material that contacts the electrodes 76, 80 to supply the voltage to the electrodes 76, 80. The guide 100 may also comprise a relatively insulating material between the electrically independent portions 104, 108 of the guide 100 and also between the guide 100 and other components of the arc spray apparatus 20 to preserve the integrity of the voltage signals applied to the electrodes 76, 80 and to isolate other portions of the arc spray apparatus 20 from the electrode voltages. Additionally, the positioning and voltage application functions of the guide 100 can be separated out into physically different components of the guide 100. For example, the guide 100 may comprise an assembly of a plurality of components that together function to position and supply voltages to the electrodes 76, 80. In one version, the guide 100 may comprise the oxygen-absorbing material 46.

The method to form the coating 32 also comprises injecting a carrier gas into the process zone 36 to direct the liquefied particles 84 of electrode material onto the component surface 28. The liquefied particles 84 splatter onto the component surface 28 where they condense and solidify to form the coating 32. In the version shown in FIG. 2, the carrier gas is flowed between the electrodes 76, 80 and through the process zone 36 to direct the liquefied metal 84. The carrier gas is injected into the process zone 36 at a sufficient pressure and flow rate to effectively transport the liquefied material 84. The carrier gas can comprise an inert or reactive gas. For example, the carrier gas can comprise nitrogen, argon, helium, neon or mixtures thereof. In the version in which the carrier gas comprises a reactive gas, the gas is selected to comprise a material which is desirable to include in the coating 32.

In the version shown in FIG. 2, the gas supply 60 comprises separate outlets into the process zone 36, a carrier gas outlet 116 and a non-oxidizing gas outlet 112, for the carrier and non-oxidizing gases, respectively. In this version, the gas supply 60 may comprise separate carrier and non-oxidizing gas valves 120, 68 to control the flow of the carrier and shield gases. However, in another version, the carrier and non-oxidizing gas flows may comprise the same gas flow. For example, the gas supply 60 may comprise a single outlet injecting a pressurized gas into the process zone 36. In this version, the pressurized gas comprises both the carrier gas and the non-oxidizing gas. Furthermore, in another version, the gas supply 60 may comprise a gas distributor that delivers a single gas to different carrier and non-oxidizing gas outlets 116, 112. In this version, the gas distributor may comprise conduits, channels, valves and other components for directing the flow of gases.

The arc spray apparatus 20 may comprise a power supply 124 to deliver voltages to the electrodes 76, 80, the guide 100, or a combination of components. The power supply 124 generates and delivers a power level suitable to generate an electric arc 72 in the process zone 36. For example, in one version, the power supply 124 generates about 5 kW to about 100 kW of power, and delivers about 5 V to about 100 V to the electrodes 76, 80 in the form of a DC voltage waveform. The arc spray apparatus 20 may also include a controller 128 to control the operation of components of the arc spray apparatus 20. For example, the controller 128 may control the generation and delivery of voltage from the power supply 124, the injection of pressurized gases into the process zone 36, and the feeding of electrode material into the process zone 36. The controller 128 may also perform other operations.

While illustrative embodiments of the method to form a coating 32 and the arc spray apparatus 20 are described in the present application, it should be understood that other embodiments are also possible. For example, the arc spray apparatus 20 may comprise additional gas flows or gas flow outlets. Furthermore, the method may comprise additional steps such as, for example, heating the component 24 or the deposited coating 32 to alter properties of the coating 32. Thus, the scope of the claims should not be limited to the illustrative embodiments.

What is claimed is:

1. A method of forming a coating on a substrate processing component surface, the method comprising:
(a) placing a shield about the component surface to define a process zone;
(b) controlling the level of oxygen present in the process zone by (i) filling the process zone with a non-oxidizing gas and maintaining a pressure p₁ in the process zone higher than a pressure p₂ of an ambient environment external to the process zone, and (ii) lining the process zone with an oxygen-absorbing material;
(c) generating an electric arc in the process zone to form a liquefied material from at least one electrode; and
(d) injecting a carrier gas into the process zone to direct the liquefied material toward the component surface to form the coating on the component surface.

2. A method according to claim 1 wherein (b) (i) comprises maintaining a separation gap between the shield and the component surface and injecting the non-oxidizing gas into the process zone at a flow rate sufficiently high to prevent gases in the ambient environment from entering the process zone through the separation gap and sufficiently low as to not disrupt the directing of the liquefied material toward the component surface.

3. A method according to claim 2 comprising maintaining a separation gap having a gap distance of about 0.1 cm to about 1.0 cm.

4. A method according to claim 1 wherein the shield comprises the oxygen-absorbing material.

5. A method according to claim 1 wherein the oxygen-absorbing material comprises an iron-containing material, silicon, a carbon-containing material, a transition-metal-containing material, ferrous oxide, ascorbic acid, isoascorbic acid, a sulfite, an alkali metal carbonate, or mixtures thereof.

6. A method according to claim 1 wherein the ratio of pressure p₁ to pressure p₂ is from about 1.5:1 to about 4:1.

7. A method according to claim 2 wherein injecting the carrier gas and injecting the non-oxidizing gas comprise injecting a single gas flow.

8. A method according to claim 1 wherein the carrier gas comprises a reactive gas.

9. A method of arc-spray coating a component surface, the method comprising:
(a) placing a shield about the component surface to define a process zone;
(b) controlling the level of oxygen present in the process zone by:
(i) filling the process zone with a non-oxidizing gas and maintaining a pressure p₁ in the process zone higher than a pressure p₂ of an ambient environment external to the process zone by:
(1) maintaining a separation gap between the shield and the component surface, and
(2) injecting the non-oxidizing gas into the process zone at a flow rate sufficiently high to prevent gases in the ambient environment from entering the process zone through the separation gap; and
(ii) lining the shield with an oxygen-absorbing material;
(c) generating an electric arc in the process zone by applying a voltage between first and second metal wires to form a liquefied metal from at least one of the wires; and
(d) injecting a carrier gas into the process zone to direct the liquefied metal toward the component surface to form the coating on the component surface.

10. A method according to claim 9 comprising injecting the non-oxidizing gas into the process zone at a flow rate sufficiently low as to not disrupt the directing of the liquefied metal towards the component surface.

11. A method according to claim 10 comprising maintaining the separation gap having a gap distance of about 0.1 cm to about 1.0 cm.

12. A method according to claim 9 wherein the ratio of pressure p₁ to pressure p₂ is from about 1.5:1 to about 4:1.

13. An arc spray apparatus comprising:
(a) a shield defining a process zone, the shield comprising an oxygen-absorbing material; and
(b) a consumable electrode extending into the process zone.

14. An arc spray apparatus according to claim 13 wherein the shield comprises a body having a coating comprising the oxygen-absorbing material.

15. An arc spray apparatus according to claim 13 wherein the oxygen-absorbing material comprises an iron-containing material, silicon, a carbon-containing material, a transition-metal-containing material, ferrous oxide, ascorbic acid, iso-ascorbic acid, a sulfite, an alkali metal carbonate, or mixtures thereof.

16. An arc spray apparatus according to claim 13 wherein the shield has a surface comprising the oxygen-absorbing material, the surface having surface features that increase its surface area.

17. An arc spray apparatus according to claim 16 wherein the surface comprising the oxygen-absorbing material has a roughness of from about 100 micro-inches to about 1,000 micro-inches.

18. An arc spray apparatus according to claim 16 wherein the surface comprising the oxygen-absorbing material is porous.

19. An arc spray apparatus according to claim 13 comprising:
(c) a guide to feed the consumable electrode into the process zone and apply a voltage to the consumable electrode; and
(d) a gas outlet to deliver a pressurized gas to the process zone.

20. An arc spray apparatus according to claim 19 comprising:
(e) a second gas outlet to deliver a second pressurized gas to the process zone.

21. An arc spray apparatus according to claim 19 wherein portions of the guide comprises the oxygen-absorbing material.

22. An arc spray apparatus, the apparatus comprising:
(a) a shield defining a process zone, the shield comprising a body having a coating, the coating comprising an oxygen-absorbing material;
(b) two consumable metal wires extending into the process zone;
(c) a guide to feed the consumable metal wires into the process zone and apply a voltage between the consumable metal wires, the guide comprising two electrically independent regions; and
(d) a first gas outlet to deliver a carrier gas to the process zone and a second gas outlet to deliver a non-oxidizing gas to the process zone.

23. An arc spray apparatus according to claim 22 wherein the oxygen-absorbing material comprises an iron-containing material, silicon, a carbon-containing material, a transition-metal-containing material, ferrous oxide, ascorbic acid, isoascorbic acid, a sulfite, an alkali metal carbonate, or mixtures thereof.
